(19) United States
(12) Patent Application Publication
(10) Pub. No.: US 2008/0070398 A1
(43) Pub. Date: Mar. 20, 2008

(54) Method For Fabricating Semiconductor Device Having Metal Fuse

(75) Inventors: Dong Su Park, Icheon-si (KR); Ho Jin Cho, Seongnam-si (KR); Keum Bum Lee, Icheon-si (KR); Su Jin Chae, Icheon-si (KR); Cheol-Hwan Park, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/758,512

(22) Filed: Jun. 5, 2007

(30) Foreign Application Priority Data
Sep. 19, 2006 (KR) 10-2006-0090847

(51) Int. Cl. H01L 23/525

(52) U.S. Cl. 438/601; 257/E23.149

(57) ABSTRACT

Disclosed herein is a method of fabricating a semiconductor device having a metal fuse. The method includes forming a plate electrode on a semiconductor substrate, forming an interlayer insulating layer on the plate electrode, forming a barrier metal layer containing either silicon or aluminum, a first metal layer and an antireflection layer containing either silicon or aluminum sequentially from bottom to top on the interlayer insulating layer. The method also includes patterning the antireflection layer, the first metal layer, and the barrier metal layer to form a first metal interconnection. The method also includes forming a fuse with the same material and structure as those of the first metal interconnection while forming the first metal interconnection. The method further includes forming an inter-metal dielectric layer on the first metal interconnection and the fuse, forming a second metal interconnection on the inter-metal dielectric layer, forming a passivation layer on the second metal interconnection, and forming a fuse box in the passivation layer.

### CROSS-REFERENCES TO RELATED APPLICATIONS

The present application claims priority to Korean patent application number 10-2006-90847, filed on Sep. 9, 2006, which is incorporated by reference in its entirety.

### BACKGROUND OF THE INVENTION

The present invention relates to a semiconductor device, and more particularly to a method of fabricating a semiconductor device having a metal fuse capable of preventing oxidation of the metal fuse and capable of preventing generation of a crack during a repair process.

A semiconductor memory device, for example, a dynamic random access memory (DRAM) may include a defective memory cell in the fabricated chip. The defective memory cell is replaced with a redundant cell, formed in advance in the chip fabrication, by performing a repair process so that a chip is normally operated.

The repair process is performed by executing a program in an internal circuit, the program for selecting a defective memory cell and replacing an address corresponding to the defective memory cell with an address signal corresponding to a redundant cell. Accordingly, in an actual use, when an address signal of a defective line is inputted, a redundant cell line is selected instead of the defective line. Among various methods for executing the program, there is a laser cutting method of applying a laser beam to the fuse to burn and cut it. An interconnection cut by the laser beam is referred to as a fuse and a region around the cut interconnection is referred to as a fuse box.

FIGS. 1A and 1B are explanatory diagrams showing a fuse region in a repair process according to the prior art.

Referring to FIG. 1A, the fuse region includes an interlayer insulating layer 102 formed on the semiconductor substrate 100, a metal interconnection 106 and a fuse 108 formed on the interlayer insulating layer 102, a passivation layer 110 formed on the fuse 1038. Further, a fuse box 112 is formed above the fuse 108 by removing a specified portion of the passivation layer 110 in order to cut the fuse by irradiating a laser beam thereto in the repair process. A contact plug 104 connects the metal interconnection 106 and the fuse 103 with an active region of the semiconductor substrate 100.

A metal material such as titanium nitride (TiN) is used for a fuse material (instead of polysilicon) in order to enhance integration and operating speed of the semiconductor device. Further, a capacitor and a fuse are simultaneously formed using plate electrode metal of a metal-insulator-metal structure to simplify fabrication steps.

However, oxidation can easily occur in a region A of an exposed interlayer insulating layer adjacent to a metal layer through contact with the atmosphere. The oxidized region is continuously oxidized during the fabrication steps, and oxidation can be accelerated while Highly Accelerated Stress Testing (HAST) is performed under high temperature and high humidity conditions. Then, as shown in FIG. 12, a crack 114 can be generated in the interlayer insulating layer due to oxidation of the metal layer forming the fuse, thereby causing a defect in the fuse.

### BRIEF SUMMARY OF THE INVENTION

Disclosed herein is a method of fabricating a semiconductor device having a metal fuse capable of suppressing oxidation of the fuse and generation of a crack around the fuse during a repair process, and preventing a device defect.

In one embodiment, the method includes forming a plate electrode on a semiconductor substrate, forming an interlayer insulating layer on the plate electrode, forming a barrier metal layer containing aluminum (Al), a first metal layer, and an antireflection layer containing aluminum (Al) sequentially from bottom to top on the interlayer insulating layer. The method also includes patterning the antireflection layer, the first metal layer, and the barrier metal layer to form a first metal interconnection. The method further includes forming a fuse with the same material and structure as those of the first metal interconnection while forming the first metal interconnection. Still further, the method includes forming an inter-metal dielectric layer on the first metal interconnection and the fuse, forming a second metal interconnection on the inter-metal dielectric layer, forming a passivation layer on the second metal interconnection, and forming a fuse box in the passivation layer.

In the method, the barrier metal layer containing aluminum (Al) may include a tantalum aluminum nitride (TaAlN) film or titanium aluminum nitride (TiAlN) film.

The antireflection layer containing aluminum (Al) may include a tantalum aluminum nitride (TaAlN) film or titanium aluminum nitride (TiAlN) film.

The layers containing aluminum (Al) may have an Al composition ratio of 10% to 50%.

The layers containing aluminum (Al) may have an Al composition ratio of 35% to 45%.

The metal interconnection may be formed of aluminum (Al) or tungsten (W), and the passivation layer may be formed of one or more layers selected from the group consisting of silicon a silicon oxide film, silicon nitride film, and a multilayer film thereof.

In another embodiment, the method includes forming a plate electrode on a semiconductor substrate, forming an interlayer insulating layer on the plate electrode, forming a barrier metal layer containing silicon (Si), a first metal layer, and an antireflection layer containing silicon (Si) sequentially from bottom to top on the interlayer insulating layer. The method also includes patterning the antireflection layer, the first metal layer, and the barrier metal layer to form a first metal interconnection. The method further includes forming a fuse with the same material and structure as those of the first metal interconnection while forming the first metal interconnection. Still further, the method includes forming an inter-metal dielectric layer on the first metal interconnection and the fuse, forming a second metal interconnection on the inter-metal dielectric layer, forming a passivation layer on the second metal interconnection, and forming a fuse box in the passivation layer.

In the method, the barrier metal layer containing silicon (Si) may include a tantalum silicon nitride (TaSiN) layer or titanium silicon nitride (TiSiN) layer.

The antireflection layer containing silicon (Si) may include a tantalum silicon nitride (TaSiN) film or titanium silicon nitride (TiSiN) film.

The layers containing silicon (Si) may have a Si composition ratio of 10% to 50%.

The layers containing silicon (Si) may have a Si composition ratio of 35% to 45%.

The metal interconnection may be formed of aluminum (Al) or tungsten (W), and the passivation layer may be formed of one or more layers selected from the group consisting of silicon oxide film, silicon nitride film, and a multilayer film thereof.

### BRIEF DESCRIPTION OF THE DRAWINGS

The above and other features, and other advantages of the present invention will be more clearly understood from the following detailed description taken in conjunction with the accompanying drawings, in which:

FIGS. 1A and 1B are explanatory diagrams showing a fuse region in a repair process according to the prior art; and

FIGS. 2 to 8 show a method of fabricating a semiconductor device having a metal fuse according to one embodiment of the present invention.

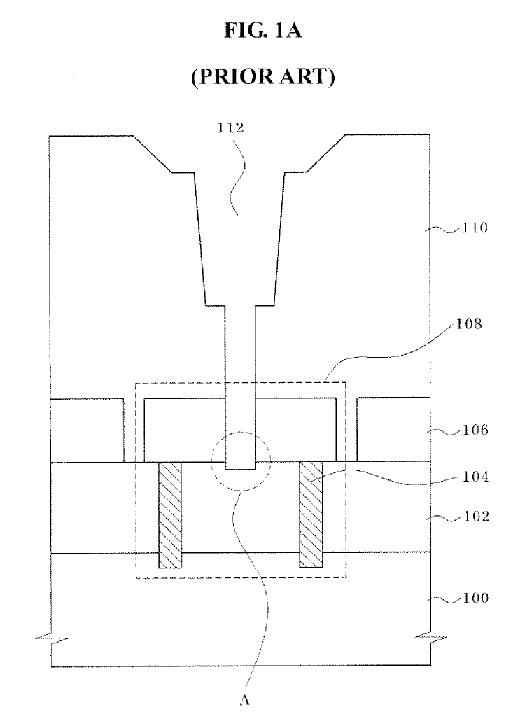

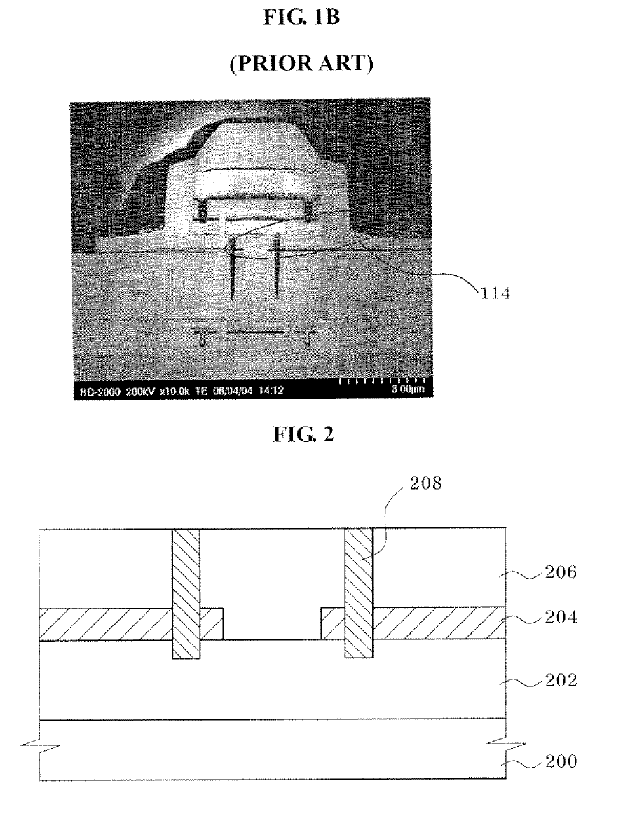

### DETAILED DESCRIPTION OF THE INVENTION

Preferred embodiments of the present invention will now be described in detail with reference to the accompanying drawings. These embodiments are used only for illustrative purposes, and the present invention is not limited thereto. In the drawings, a thickness is enlarged to clearly show several layers and regions, and like reference numerals designate like parts having practically the same functions.

FIGS. 2 to 8 show a method of fabricating a semiconductor device having a metal fuse according to one embodiment of the present invention. The embodiment of the present invention will be described by showing only a fuse region of the semiconductor device.

Referring to FIG. 2, a first interlayer insulating layer 202 is formed on a semiconductor substrate 200. Although not shown for simplicity in the drawing, a semiconductor device connected to metal interconnection, for example, a lower structure such as a word line or bit line is formed on the semiconductor substrate 200.

Next, a plate electrode 204 is formed on the first interlayer insulating layer 202.

The plate electrode 204 may be formed of a titanium nitride (TiN) layer by using a chemical vapor deposition (CVD) method or an atomic layer deposition (ALD) method. Further, the plate electrode 204 may be formed of double layers including a titanium nitride (TiN) layer formed by using the chemical vapor deposition (CVD) method and a low-stress titanium nitride (TiN) layer formed by using a physical vapor deposition (PVD) method. Further, the plate electrode 204 may be formed of electrode metal material including ruthenium (Ru) or tantalum nitride (TaN).

Thereafter, a second interlayer insulating layer 206 with a first contact plug 208 is formed on the plate electrode 204. The first contact plug 208 connects the lower structure formed on the semiconductor substrate 200 with metal interconnection formed in the following step. The first contact plug 208 may be formed of a tungsten (W) layer.

Specifically, after the second interlayer insulating layer 206 is formed on the plate electrode 204, the second interlayer insulating layer 206 is selectively etched to form a contact hole (not shown) that exposes an active region of the lower structure. Then, a semiconductor layer to be buried in the contact hole is deposited and a planarization process, for example, a chemical mechanical polishing (CMP) process or an etch back process, is performed to form the first contact plug 208. In this case, the first interlayer insulating layer 202 and the second interlayer insulating layer 206 may be formed of a single layer or a multilayer layer by selecting at least one from the group consisting of a low pressure tetraethoxysilane (LPTEOS) oxide layer, plasma enhanced tetraethylorthosilicate (PETEOS) oxide layer, undoped silicate glass (USG) layer, borophosphosilicate glass (BPSG) layer and phosphosilicate glass (PSG) layer.

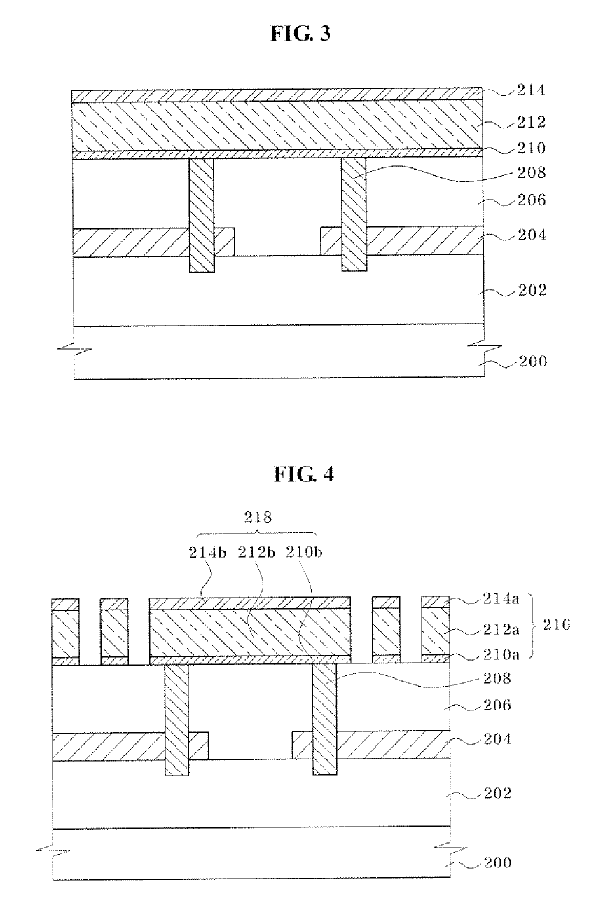

Next, referring to FIG. 3, a barrier metal layer 210 is formed on the second interlayer insulating layer 206.

The barrier metal layer 210 is conventionally formed of titanium nitride (TiN). When titanium nitride TiN is used for the barrier metal layer, however, while Highly Accelerated Stress Testing (HAST) is performed under high temperature and high humidity conditions to examine device characteristics, oxidation can easily occur due to reaction between a metal layer forming the plate electrode and atmosphere (O₂). When the metal layer is oxidized, a crack is generated in the interlayer insulating layer by oxidation reaction, thereby causing a defect in the fuse.

Accordingly, metal material containing aluminum (Al) is employed for the barrier metal layer 210 to prevent diffusion of an oxidation source. The barrier metal layer 210 containing aluminum (Al) can be formed by using a method selected from the group consisting of a chemical vapor deposition (CVD) method, plasma enhanced CVD (PECVD) method, atomic layer deposition (ALD) method and plasma enhanced ALD (PEALD) method. The barrier metal layer 210 containing aluminum (Al) may be formed of a tantalum aluminum nitride (TaAlN) layer or titanium aluminum nitride (TiAlN) layer. In this case, a thin layer of tantalum aluminum nitride (TaAlN) may have an Al composition ratio of 10% to 50%, preferably 35% to 45%, to improve oxidation resistance. Further, the barrier metal layer 210 may be formed using a material capable of preventing diffusion of the oxidation source, for example, a metal material containing silicon (Si). In this case, the barrier metal layer 210 containing silicon (Si) may be formed to include a tantalum silicon nitride (TaSiN) layer or titanium silicon nitride (TiSiN) layer.

Next, a first metal layer 212 and an antireflection layer 214 containing aluminum (Al) are sequentially deposited on the barrier metal layer 210 containing aluminum (Al). The barrier metal layer 210, the first metal layer 212 and the antireflection layer 214 are used to form the metal interconnection and fuse in the following step. In this case, the first metal layer 212 may be formed to include aluminum (Al) or tungsten (W).

Further, the antireflection layer 214 containing aluminum (Al) can be formed by using a method selected from the group consisting of the chemical vapor deposition (CVD) method, plasma enhanced CVD (PECVD) method, atomic layer deposition (ALD) method, and plasma enhanced ALD (PEALD) method. The antireflection layer 214 containing aluminum (Al) may be formed of a tantalum aluminum nitride (TaAlN) layer or titanium aluminum nitride (TiAlN) layer. Further, the antireflection layer 214 may be formed using a material capable of preventing diffusion of the oxidation source, for example, a metal material containing silicon (Si). In this case, the antireflection layer 214 containing silicon (Si) may be formed to include a tantalum silicon nitride (TaSiN) layer or titanium silicon nitride (TiSiN) layer.

When the barrier metal layer or the antireflection layer is formed using the metal material containing aluminum (Al), aluminum (Al) reacts with oxygen in the atmosphere to form a TaAlNO layer, serving as a surface oxide layer on a layer interface. Along with oxidation combining aluminum (Ai) in the surface oxide layer with oxygen O₂, the structure thereof becomes dense. Accordingly, although the oxidation is performed near the interface, the aluminum structure combined with oxygen becomes still denser, thereby preventing the oxidation source from diffusing through the layer and penetrating the lower structure. Thus, it is possible to prevent the oxidation from further proceeding.

Conventionally, when the barrier metal layer is formed using a titanium nitride (TiN) layer, an oxidation source material penetrates the lower structure of the device through the relatively sparse structure, thereby causing a defect such as a crack. In comparison, the barrier metal layer containing aluminum (Al), for example, a tantalum aluminum nitride (TaAlN) layer, has a layer structure relatively denser than the titanium nitride (TiN) layer, thereby interrupting penetration of oxidation material. Thus, a crack is prevented from being generated in the interlayer insulating layer due to the oxidation reaction, thereby preventing a defect in the fuse.

The metal material containing aluminum (Al) having a higher Al composition ratio can more favorably prevent diffusion of an oxidation source (oxygen) by forming a TaAlNO layer serving as a surface oxide layer. Accordingly, it is preferable that a thin layer of the barrier metal layer 210 containing aluminum (Al) or the antireflection layer 214 has an Al composition ratio of 10% to 50% to improve oxidation resistance.

Referring to FIG. 4, a first metal interconnection 216 and a fuse 218 are formed by patterning the antireflection layer 214 containing aluminum (Al), the first metal layer 212, and the barrier metal layer 210. The first metal interconnection 216 includes an antireflection layer pattern 214a containing aluminum (Al), a first metal layer pattern 212a, and a barrier metal layer pattern 210a. The fuse 218 includes an antireflection layer pattern 214b containing aluminum (Al), a first metal layer pattern 212b, and a barrier metal layer pattern 210b.

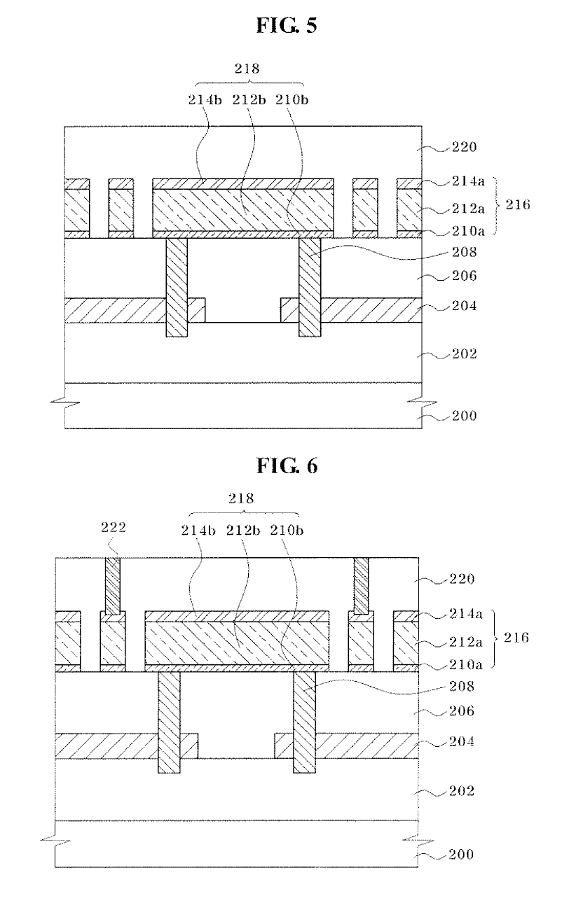

Referring to FIG. 5, an inter-metal dielectric (IMB) layer 220 is formed to bury the first metal interconnection 216 and the fuse 218. The inter-metal dielectric layer 220 may be formed of a single layer or a multilayer layer by selecting at least one from the group consisting of a LPTEOS oxide layer, PETEOS oxide layer, USG layer, BPSG layer and PSG layer.

Referring to FIG. 6, a contact hole that selectively exposes the first metal interconnection 216 is formed by etching the inter-metal dielectric layer 220. Next, a semiconductor layer, for example, a polysilicon layer, is buried in the contact hole. Thereafter, a planarization process, for example, a chemical mechanical polishing (CMP) process for polishing the semiconductor layer, is performed to form a contact plug 222. In this case, the fuse 218 is isolated by the inter-metal dielectric layer 220.

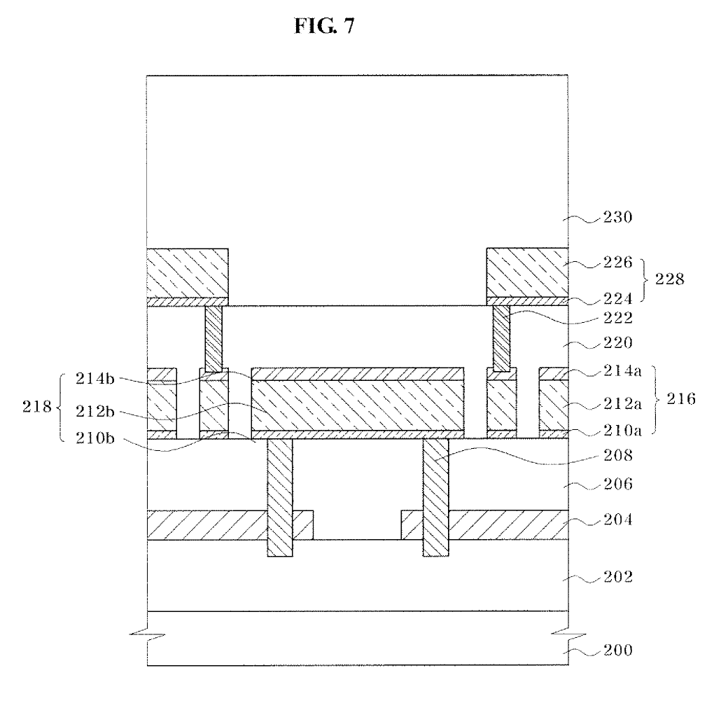

Referring to FIG. 7, a second metal interconnection 228 is formed on the contact plug 222.

Specifically, a second barrier metal layer and a second metal layer are formed on the contact plug 222. Thereafter, the second metal interconnection 228, including a second barrier metal layer pattern 224 and a second metal layer pattern 226 that are sequentially stacked, is formed by patterning the second barrier metal layer and second metal layer.

A passivation layer 230 is then thickly formed to bury the second metal interconnection 228 and the fuse 218. In this case, the passivation layer 230 may be formed of a single layer of a silicon oxide layer or silicon nitride layer, or a multilayer layer thereof.

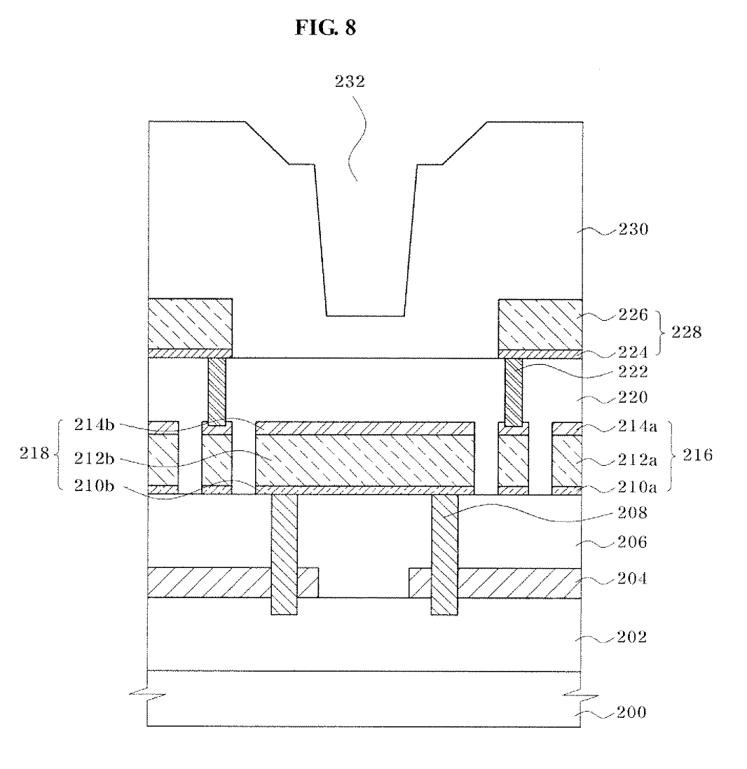

Referring to FIG. 8, a photoresist layer is coated on the passivation layer 230 and patterned to selectively expose the passivation layer 230, thereby forming a photoresist layer pattern (not shown) defining a region in which a fuse box is formed. Then, the passivation layer 230 is etched through an etching mask of the photoresist layer pattern until the passivation layer 230 above the fuse has a specified thickness, thereby forming a fuse box 232. The fuse 218 can safely blow by the fuse box 232 when the laser is irradiated during a repair process.

In the method of fabricating a semiconductor device having a metal fuse according to the present invention, the barrier metal layer is formed of a material containing aluminum (Al) or silicon (Si) with high oxidation resistance, so that an oxidation source can be prevented from diffusing through the layer. Thus, a crack is prevented from being generated in the interlayer insulating layer due to the oxidation reaction, thereby preventing a defect in the fuse.

As described above, according to the present invention, there is provided a method of fabricating a semiconductor device having a metal fuse, wherein a material with high oxidation resistance is used for the metal interconnection to prevent a crack from being generated in the interlayer insulating layer due to an oxidation reaction between a metal layer and atmosphere. Therefore, it is possible to prevent a defect in the fuse due to a crack formed in the interlayer insulating layer during a repair process.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method of fabricating a semiconductor device having a metal fuse, the method comprising:
forming a plate electrode over a semiconductor substrate;
forming an interlayer insulating layer over the plate electrode;
forming a contact plug inside the interlayer insulating layer, and the contact plug connecting the semiconductor substrate to a metal layer;
forming a barrier metal layer containing aluminum (Al) a metal layer and an antireflection layer containing aluminum (Al) sequentially from bottom to top over the interlayer insulating layer;
patterning the antireflection layer, the first metal layer, and the barrier metal layer to form a first metal interconnection;
forming a fuse with the same material and structure as those of the first metal interconnection while forming the first metal interconnection;
forming an inter-metal dielectric layer over the first metal interconnection and the fuse;
forming a second metal interconnection over the inter-metal dielectric layer;
forming a passivation layer on the second metal interconnection; and
forming a fuse box in the passivation layer.

2. The method according to claim 1, wherein the barrier metal layer containing aluminum (Al) includes a tantalum aluminum nitride (TaAlN) film or titanium aluminum nitride (TiAlN) film.

3. The method according to claim 1, wherein the antireflection layer containing aluminum (Al) includes a tantalum aluminum nitride (TaAlN) film or titanium aluminum nitride (TiAlN) film.

4. The method according to claim 1, wherein the layers containing aluminum (Al) have an Al composition ratio of 10% to 50%.

5. The method according to claim 1, wherein the layers containing aluminum (Al) have an Al composition ratio of 35% to 45%.

6. The method according to claim 1, wherein the metal interconnection is formed of aluminum (Al) or tungsten (W).

7. The method according to claim 1, wherein the passivation layer is formed of one or more layers selected from the group consisting of silicon oxide film, silicon nitride film, and silicon oxinitride film thereof.

8. A method of fabricating a semiconductor device having a metal fuse, comprising:
forming a plate electrode over a semiconductor substrate;
forming an interlayer insulating layer over the plate electrode;
forming a barrier metal layer containing silicon (Si), a metal layer and an antireflection layer containing silicon (Si) sequentially from bottom to top over the interlayer insulating layer;
patterning the antireflection layer, the first metal layer, and the barrier metal layer to form a first metal interconnection;
forming a fuse with the same material and structure as those of the first metal interconnection while forming the first metal interconnection;
forming an inter-metal dielectric layer over the first metal interconnection and the fuse;
forming a second metal interconnection over the inter-metal dielectric layer;
forming a passivation layer over the second metal interconnection; and
forming a fuse box in the passivation layer.

9. The method according to claims, wherein the barrier metal layer containing silicon (Si) includes a tantalum silicon nitride (TaSiN) film or titanium silicon nitride (TiSiN) film.

10. The method according to claim 8, wherein the antireflection layer containing silicon (Si) includes a tantalum silicon nitride (TaSiN) film or titanium silicon nitride (TiSiN) film.

11. The method according to claim 8, wherein the layers containing silicon (Si) have a Si composition ratio of 10% to 50%.

12. The method according to claim 8, wherein the layers containing silicon (Si) have a Si composition ratio of 35% to 45%.

13. The method according to claim 8, wherein the metal interconnection is formed of aluminum (Al) or tungsten (W).

14. The method according to claim 8, wherein the passivation layer is formed of one or more layers selected from the group consisting of silicon oxide film, silicon nitride film, and a multilayer film thereof.
